(19) United States
(12) Patent Application Publication
(10) Pub. No.: US 2010/0019346 A1
(43) Pub. Date: Jan. 28, 2010

(54) IC HAVING FLIP CHIP PASSIVE ELEMENT AND DESIGN STRUCTURE

(76) Inventors: Mete Erturk, St. Albans, VT (US); Edmund J. Sprogis, Underhill, VT (US); Anthony K. Stamper, Williston, VT (US)

Correspondence Address: HOFFMAN WARNICK LLC, 75 STATE ST, 14TH FLOOR, ALBANY, NY, 12207, US

(21) Appl. No.: 12/180,810

(22) Filed: Jul. 28, 2008

(51) Int. Cl. H01L 29/00

(52) U.S. Cl. 257/531; 257/E29.001

(57) ABSTRACT

IC and design structure including various ways of raising a passive element such as an inductor off the surface of the substrate to improve the performance of the passive element are presented. A first wafer may be provided, and passive elements diced from a second wafer. The passive elements are flipped, and then aligned to be bonded on the first wafer such that the passive elements are raised a distance off the first wafer because of the presence of chip connections such as C4 solder bumps. A gap between the passive elements and the first wafer can be filled with underfill or air. If air is used, a hermetic seal around the gap can be created using chip connections such as C4 solder bumps or other known bonding means to seal the gap.

The current application is related to co-pending U.S. patent application Ser. No. ______, Attorney Docket No. BUR920080112US1, filed on ______.

### BACKGROUND

1. Technical Field

The disclosure relates generally to semiconductor device fabrication, and more particularly, to methods of forming silicon carrier on-chip passive element.

2. Background Art

On-chip inductors are formed by fabricating single level or multi-level wiring spirals (FIGS. 1A-1C). These wiring spirals typically use wires with widths of 5-30 microns and heights of 1-4 microns; and the inductor diameter typically is 30-300 microns. An exemplary example of a single spiral inductor formed on a CMOS wafer is shown in FIG. 1A. This inductor is formed with the last wiring level on the chip and has no active wiring under the inductor; and is contacted at points A and B. An optional first wiring level (M1) ground plane, which can be used to reduce rf noise and increase quality factor by reducing losses in the substrate, could also be included. However, using a ground plane increases the capacitive load on the inductor, decreasing its self resonance frequency, and essentially limiting the frequency range of operation for the inductor. It is of great value if substrate losses can be reduced without a ground plane. FIG. 1B shows an example of a single level three turn inductor. FIG. 1C shows an example of a multi-level three turn inductor, as known in the art. Two levels of wiring are used for the FIG. 1C inductor, with overpasses C and D and optional strapping of the upper wiring level with the lower wiring level (dotted line) to reduce the resistance. An On-Chip inductor performance is limited, among other factors, by capacitive and magnetic coupling to a substrate. For CMOS technologies, the maximum inductor height off the substrate is approximately 5 μm, which limits the inductor quality factor Q to approximately 25. The quality factor Q of an inductor can be found through the following formula, where R is its internal electrical resistance and ωL is Capacitive or Inductive reactance at resonance: Q=ωL/R. This limitation also limits the optimal inductor thickness to approximately 6 μm, which limits the inductor resistance and ties into the maximum achievable Q. As the inductor thickness is increased beyond 6 um, the increasing fringe capacitance from the traces to substrate offset the benefit of decreased resistance within the traces. FIG. 1D shows an example of inductor quality factor for inductors fabricated on chip, with a 5 micron spacing over the substrate; and an inductor fabricated using this disclosure, with a 25 micron spacing over the substrate. By increasing the spacing between the inductor and the substrate, the quality factor and also the frequency range of operation for the inductor are increased.

### SUMMARY

A first aspect of this disclosure includes a method of forming an on-chip passive element, the method comprising: providing a first wafer, including a substrate with at least one layer thereon, wherein a top most layer includes at least one metal receiving pad thereon; providing at least one passive element, diced from a second wafer, including a substrate with at least one layer thereon, wherein at least one chip connection is deposited on one of the passive elements; flipping the at least one passive element; aligning the at least one passive element with the first wafer so that the at least one chip connection of the at least one passive element are aligned with the receiving pads of the first wafer; bonding the first wafer and the at least one passive element together such that the at least one passive element is raised off the first wafer.

A second aspect includes an integrated circuit (IC) comprising: two or more bonded chips including: a first chip from a first wafer, the first chip including a substrate with at least one layer thereon, wherein a top most layer includes at least one metal receiving pad thereon; a second chip from a second wafer, the second chip including a substrate with at least one layer thereon, wherein the at least one layer includes at least one passive element, and wherein at least one chip connection is deposited on one of the passive elements; and wherein the second chip is flipped and aligned with the first chip so that the at least one chip connection of the at least one passive element are aligned with the receiving pads of the first chip, and the first chip and the second chip are bonded together such that the second chip is raised off the first chip. A third aspect includes a design structure embodied in a machine readable medium for designing, manufacturing, or testing an integrated circuit, the design structure comprising the above-described IC.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1A-1C shows existing prior art inductors.

FIG. 1D is a chart showing inductor quality factor for inductors fabricated on chip.

FIGS. 2-5B show the structure and method disclosed in this disclosure.

FIGS. 6-7 show alternative embodiments of the structure disclosed in this disclosure.

FIG. 8 shows a spiral planer inductor as known in the art.

FIG. 9 is a flow diagram of a design process used in semiconductor design, manufacture, and/or test.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As discussed above, on-chip inductor performance is limited when conventional methods are used for on-chip wiring to form the inductor. The solution disclosed in this disclosure involves various ways of raising an inductor, or other passive elements, off the surface of the substrate to improve the performance of the inductor.

First, an integrated circuit is formed on a wafer with a specific chip size. Next, inductors are fabricated on a second wafer as commonly known in the art such that the chip size of the inductors on the second wafer is equal to or smaller than the chip size of the integrated circuit formed on the first wafer. Complete inductors can be fabricated on the second wafer, or only the upper wires of an inductor. The inductor chips are then diced from the second wafer using conventionally known means and then the chips from the second wafer are attached to chips from the first wafer to provide inductors for the integrated circuits from the first wafer spaced, for example, 30 microns over the first wafer substrate. Alternatively, the first and second wafers are bonded together and then diced.

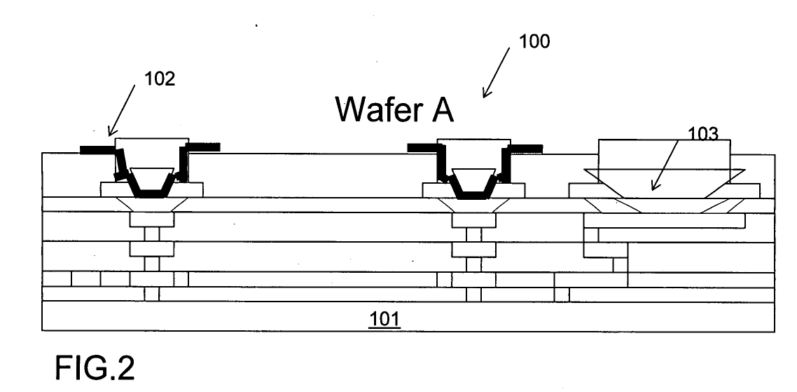

As shown in FIG. 2, a first wafer 100, for example, an integrated CMOS wafer, is provided. The wafer of FIG. 2 is shown with a Si substrate 101, several levels on top of the substrate, Tungsten stud contacts, copper wires, vias, etc., and other features and layers, such as transistors, capacitors, etc., as known in the art. Substrates other than Si can also be used, including silicon-on-insulator or GaAs. The CMOS wafer of FIG. 2, referred herein as wafer A, is also shown with a last wire aluminum-copper (AlCu) level 103, as known in the art, which can be used to make wirebond pads or solder bump pads. The last wire AlCu wire level could be cladded with refractory metals, such as TiN, below and/or above, as known in the art. Also shown is a deposited metal that acts as a receiving pad 102 for a chip connection such as a C4 solder bump, discussed in more detail below. Receiving pad 102 can consist of thin layers of metals used to contact solder bumps, such as TiW/Au as known in the art, to act as a receiving pad, and is applied using commonly known methods in the art, including a plating process using a riston photomask tape.

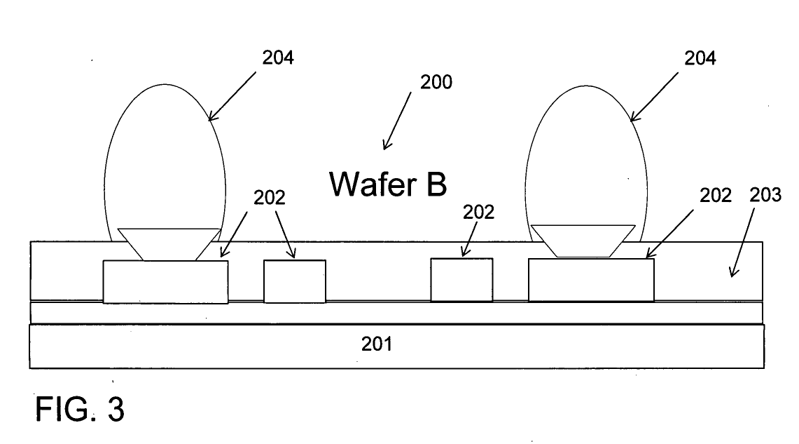

Next, a second wafer 200 is disclosed as seen in FIG. 3, referred to herein as wafer B. This wafer includes a substrate 201, which can be silicon (standard 0.1-1000 i-cm resistivity), high resistivity silicon (100,000 Ω-cm or higher resistivity), glass (insulator), quartz (insulator), or any other material known in the art. If silicon is used, a dielectric such as SiO2 deposited using any known method including liquid phase chemical vapor deposition (LPCVD), rapid thermal CVD (RTCVD), or plasma enhanced CVD (PECVD), can be used as the level immediately on top of the substrate to provide insulation. The goal is to reduce or eliminate eddy current loses in the chip substrate which will ultimately be bonded to the first wafer as discussed below.

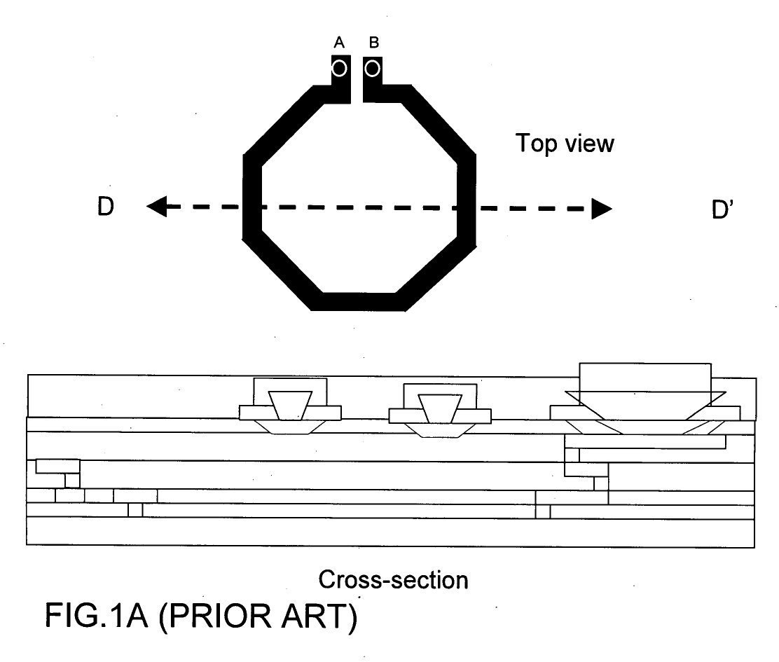

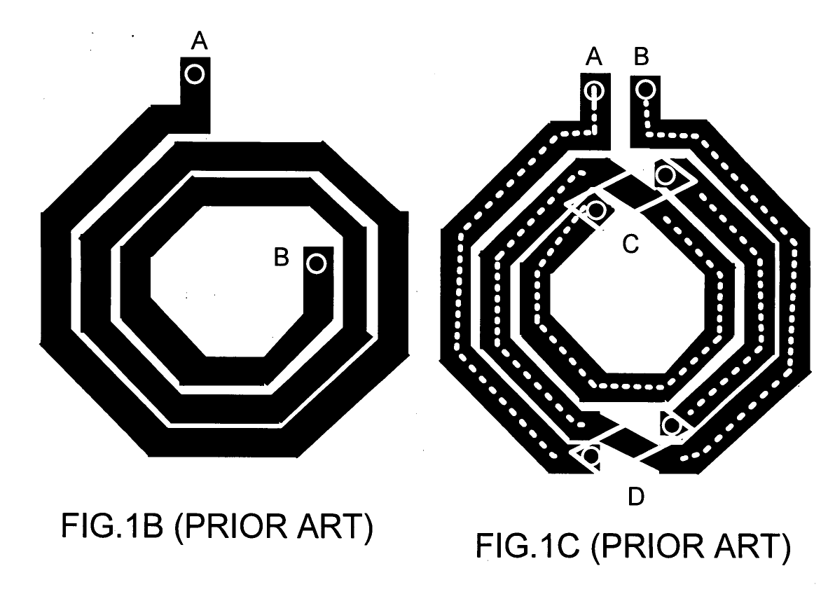

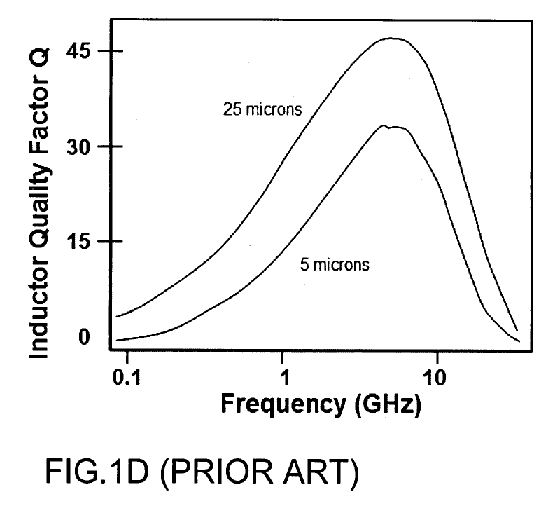

Inductor wire spirals 202 are then provided on the substrate, or the layer above the substrate. Insulation 203 is also provided on top of the wires. The inductor wire spirals are shown as a single layer but could also be multi-layers with over/under pass through connections as discussed previously in FIGS. 1A-1D. The pass through connections could be formed on wafer B, i.e. multi-level wire inductors would be formed on wafer B; or they could be formed using the controlled collapse chip connection (C4) solder bumps and wires on wafer A. C4 solder bumps 204 are then formed on the wires. Although C4 solder bumps are described in this disclosure, any now known, or later developed chip connection for bonding chips or wafers can be used, including copper pillars, as known in the art.

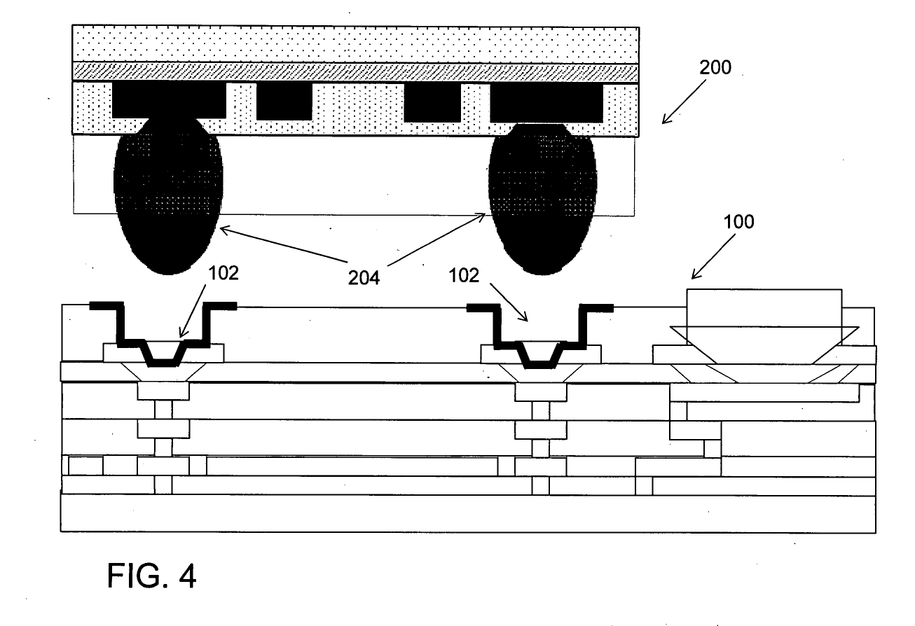

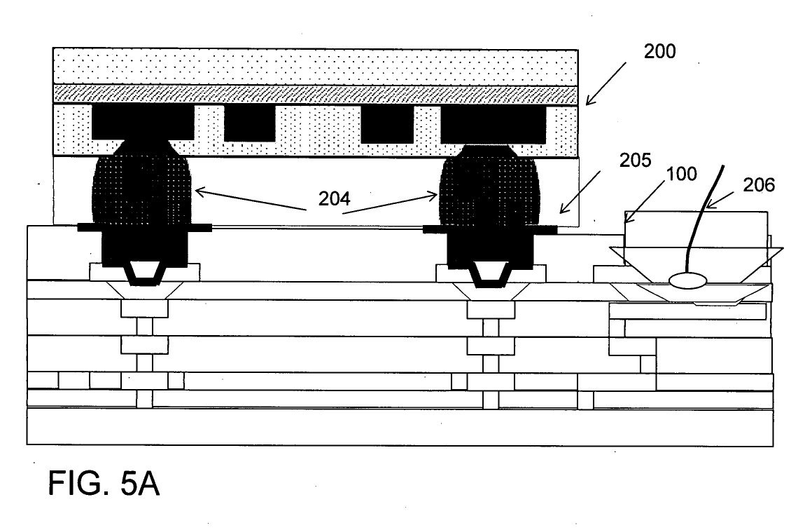

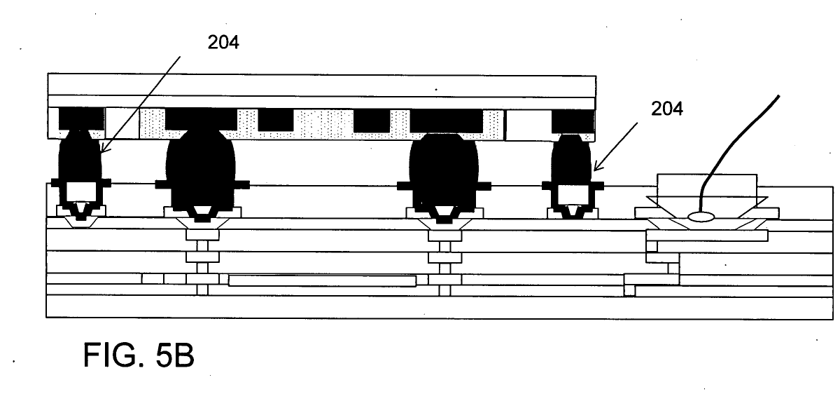

FIG. 4 shows both the first wafer and chips diced from the second wafer. Chips, i.e. passive elements, from wafer B are flipped, aligned with wafer A, and mated with wafer A as shown in FIG. 3. The C4 solder bumps 204 are aligned such that they will mate with the receiving pads 102 of wafer A. Mating the chips in this way allows a gap 205 between wafer A and wafer B (shown in FIG. 5B). This gap 205 means that the inductors will be approximately 20-100 μm off the surface of wafer A. The inductors could be approximately 4-20 μm tall which would result in Q values of up to 20× standard inductors. Underfill may optionally be provided on wafer B to fill the gap between wafer A and wafer B once mated, as known in the art. It should be noted that although this disclosure and the FIGS. refer to the top wafer as being flipped and aligned with the bottom wafer, the opposite is disclosed as well. The lower, or bottom, passive elements or chips, can be flipped and aligned to be mated with an upper wafer.

FIG. 5A shows wafer A and chips from wafer B after they have been bonded together. The bonding can be performed by annealing so that the C4 solder bumps 204 are reflowed so that they will adhere better to the receiving pads. Also shown in FIG. 5A, a wire bond 206 can be attached to wafer A at the aluminum layer discussed above. For this embodiment, after chips from wafer B are bonded to wafer A, the composite chips on wafer A would be diced and packaged. It is shown in the FIGS. that the chip from wafer B is smaller than the chip from wafer A, but it also could be the same size. One or more chips from wafer B or another wafer could be bonded to wafer A. Finally, wafer B in its entirety could be bonded to wafer A prior to dicing. This option would require that the wafer A and B chip sizes be similar or identical and on identical pitches.

FIG. 5A shows the wafer and chip bonded together with an underfill, such as epoxy as known in the art, filling a gap 205 between the two wafers. However, alternatively, no underfill could be used (FIG. 5B), and there could be an air in the gap 205 between the two wafers, resulting in lower capacitance between the inductor and the wafer A substrate. Lower capacitance because of the air gap would result in a reduction of eddy currents in wafer A. If an air gap is used instead of an underfill, typically additional C4 solder bumps 204 are provided to provide a ring around wafer B to provide a hermetic seal around the air gap, as shown in FIG. 5B.

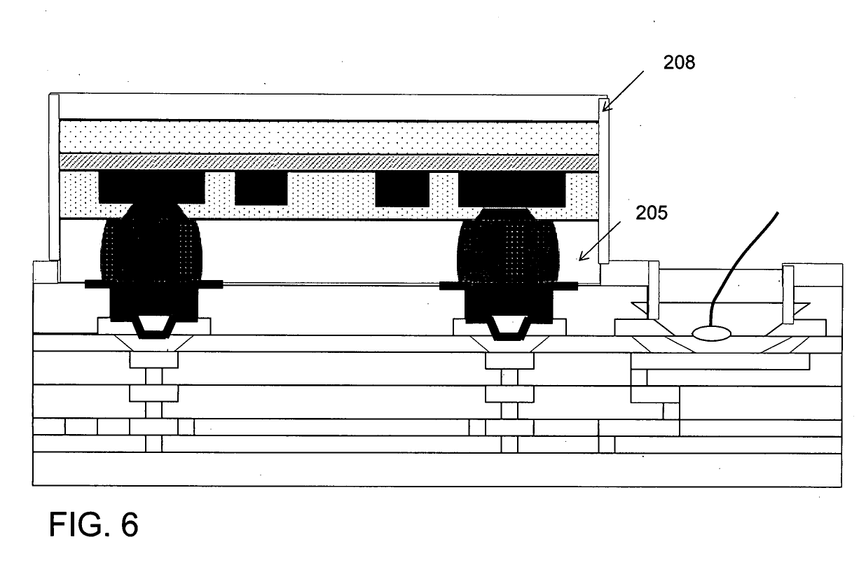

Additionally, as shown in FIG. 6, a passivation layer 208 can be added over the wafers after wafer A and wafer B have been bonded together. The passivation layer 208 can be applied using PVD, chemical vapor deposition (CVD), PECVD, or any known method and can consist of any dielectric material, including one or more of polyimide, silicon dioxide, silicon nitride, etc., as known in the art. The passivation layer improves packaging reliability by preventing mechanical damage during packaging, providing a hermetic seal, etc. FIG. 6 also shows underfill in the gap 205 between wafer A and wafer B, but as discussed above, there may be air between the wafers instead of the underfill.

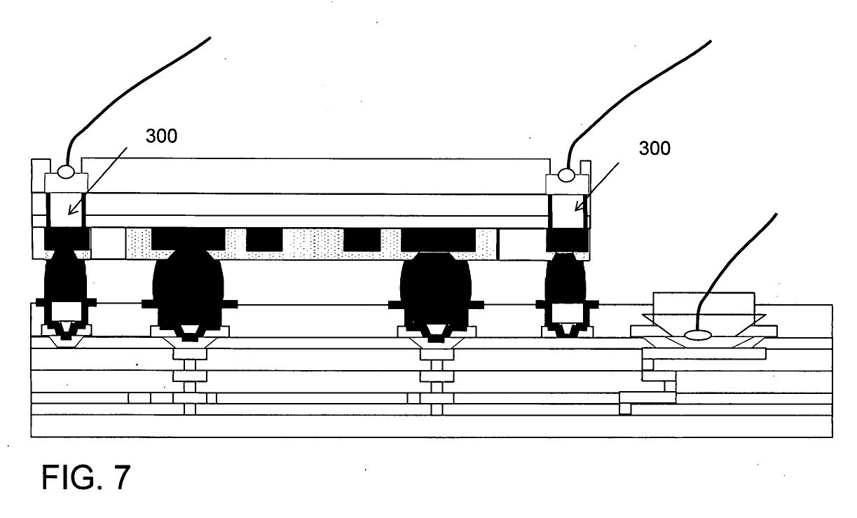

FIG. 7 shows an alternative embodiment for the structure of wafer B that includes insulated through silicon vias (TSV) 300. These vias 300 are commonly known in the art, and are typically approximately 10-200 μm tall. As shown in FIG. 7, the vias allow access through wafer B to the diced chips. The vias 300 can be fabricated once the wafers have been bonded together, or on the front end, i.e., while wafer B is being fabricated prior to bonding with wafer A. The TSVs 300 on chips from wafer B can be contacted using C4 solderbumps or wirebonds, or other chip connection methods commonly known in the art. Also, while FIG. 7 shows a wirebonds on wafer A, such wirebonds are optional.

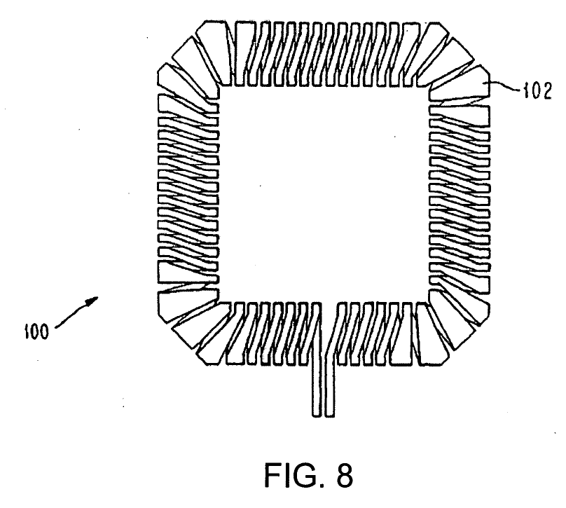

The inductors used in this disclosure can be spiral planar inductors that are perpendicular to the substrate on wafer B. Alternatively, the inductors may be parallel to the substrate on wafer B as shown in FIG. 8, which was published in U.S. Pat. No. 5,793,272.

Although inductors from wafer B bonded to wafer A are shown, it is also disclosed to bond chips from multiple wafers (C, D, etc.) to wafer A with passive elements, such as inductors, or other elements. It is also noted that although inductors are referred to in this disclosure, other passive elements such as micro-transmission lines, or transmission lines can be used as well, especially since these passive elements would also benefit from being raised off the wafer as discussed herein.

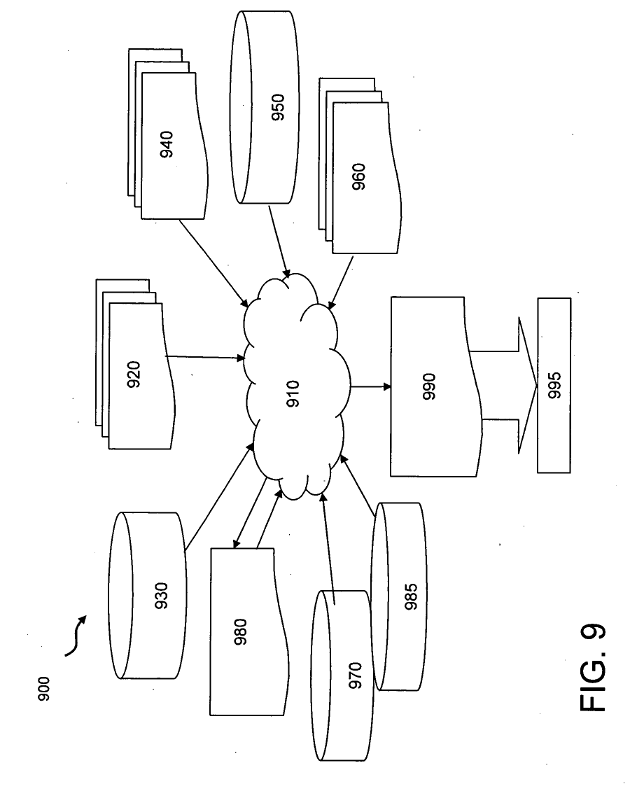

FIG. 9 shows a block diagram of an exemplary design flow 900 used for example, in semiconductor IC logic design, simulation, test, layout, and manufacture. Design flow 900 includes processes and mechanisms for processing design structures to generate logically or otherwise functionally equivalent representations of the embodiments of the disclosure shown in FIGS. 5-7. The design structures processed and/or generated by design flow 900 may be encoded on machine-readable transmission or storage media to include data and/or instructions that when executed or otherwise processed on a data processing system generate a logically, structurally, or otherwise functionally equivalent representation of hardware components, circuits, devices, or systems.

FIG. 9 illustrates multiple such design structures including an input design structure 920 that is preferably processed by a design process 910. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission or storage medium, design structure 920 may be accessed and processed by one or more hardware and/or software modules within design process 910 to simulate or otherwise functionally represent an electronic component, circuit, electronic or logic module, apparatus, device, or system such as those shown in FIGS. 5-7. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown in FIGS. 5-7 to generate a netlist 980 which may contain design structures such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is re-synthesized one or more times depending on design specifications and parameters for the device. As with other design structure types described herein, netlist 980 may be recorded on a machine-readable data storage medium. The medium may be a non-volatile storage medium such as a magnetic or optical disk drive, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 970, and test data files 985 which may include input test patterns, output test results, and other testing information. Design process 910 may further include modules for performing standard circuit design processes such as timing analysis, verification, design rule checking, place and route operations, etc.

Design process 910 employs and incorporates well-known logic and physical design tools such as HDL compilers and simulation model build tools to process design structure 920 together with some or all of the depicted supporting data structures to generate a second design structure 990. Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the disclosure shown in FIGS. 5-7. In one embodiment, design structure 990 may comprise a compiled, executable HDL simulation model that functionally simulates the devices shown in FIGS. 5-7.

Design structure 990 may also employ a data format used for the exchange of layout data of integrated circuits and/or symbolic data format (e.g. information stored in a GDSII (GDS2), GL1, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data processed by semiconductor manufacturing tools to fabricate embodiments of the disclosure as shown in FIGS. 5-7. Design structure 990 may then proceed to a stage 995 where, for example, design structure 990: proceeds to tape-out, is released to manufacturing, is released to a mask house, is sent to another design house, is sent back to the customer, etc.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the FIG. or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. An integrated circuit (IC) comprising:
two or more bonded chips including:
a first chip from a first wafer, the first chip including a substrate with at least one layer thereon, wherein a top most layer includes at least one metal receiving pad thereon;
a second chip from a second wafer, the second chip including a substrate with at least one layer thereon, wherein the at least one layer includes at least one passive element, and wherein at least one chip connection is deposited on one of the passive elements; and
wherein the second chip is flipped and aligned with the first chip so that the at least one chip connection of the at least one passive element are aligned with the receiving pads of the first chip, and the first chip and the second chip are bonded together such that the second chip is raised off the first chip.

2. The IC of claim 1, wherein the passive element is an inductor or a transmission line.

3. The IC of claim 1, wherein only one passive element is flipped and bonded to the first wafer.

4. The IC of claim 1, wherein there are multiple passive elements which include passive elements diced from different wafers.

5. The IC of claim 1, wherein the at least one passive element consists of the entire second wafer.

6. The IC of claim 1, wherein the at least one passive element is raised approximately 20-100 μm off the first wafer.

7. The IC of claim 1, wherein an underfill material is provided in a space between the first wafer and the at least one passive element that is formed after bonding.

8. The IC of claim 1, wherein a space between the first wafer and the at least one passive element that is formed after bonding is filled with air.

9. The IC of claim 8, further comprising additional chip connections to provide a ring around the at least one passive element to provide a hermetic seal around the space.

10. The IC of claim 1, wherein the substrate includes at least one of: a semiconductor, a dielectric, a glass, a metal, nonmetallic conductor, magnetic material and a polymer.

11. The IC of claim 1, wherein each of the at least one chip connection includes a C4 solder bump or a copper pillar.

12. The IC of claim 1, wherein the at least one passive element further includes at least one wire inductor and at least one insulated through silicon via.

13. The IC of claim 12, wherein the through silicon vias are approximately 10-200 μm tall.

14. The IC of claim 12, wherein a C4 solder bump is formed on the backside of the second wafer, and a wirebond is formed on the surface of the first wafer.

15. The IC of claim 12, wherein a wirebond is formed on the backside of the second wafer, and a wirebond is formed on the surface of the first wafer.

16. A design structure embodied in a machine readable medium for designing, manufacturing, or testing an integrated circuit, the design structure comprising:
two or more bonded chips including:
a first chip from a first wafer, the first chip including a substrate with at least one layer thereon, wherein a top most layer includes at least one metal receiving pad thereon;
a second chip from a second wafer, the second chip including a substrate with at least one layer thereon, wherein the at least one layer includes at least one passive element, and wherein at least one chip connection is deposited on one of the passive elements; and
wherein the second chip is flipped and aligned with the first chip so that the at least one chip connection of the at least one passive element are aligned with the receiving pads of the first chip, and the first chip and the second chip are bonded together such that the second chip is raised off the first chip.

17. The design structure of claim 16, wherein the passive element is an inductor or a transmission line.

18. The design structure of claim 16, wherein the design structure includes at least one of test data, characterization data, verification data, or design specifications.

19. The design structure of claim 16, wherein the design structure comprises a netlist.

20. The design structure of claim 16, wherein the design structure resides on storage medium as a data format used for the exchange of layout data of integrated circuits.
